(19) United States
(12) Patent Application Publication
(10) Pub. No.: US 2007/0208979 A1
(43) Pub. Date: Sep. 6, 2007

(54) Split clock scan flip-flop

(75) Inventor: Pu-Jen Cheng, Yongkang City (TW)

Correspondence Address: Howard Chen, Esq.;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/331,566

(22) Filed: Jan. 13, 2006

(51) Int. Cl. G01R 31/28

(52) U.S. Cl. 714/731

(57) ABSTRACT

A split clock flip-flop (SC-SFF) includes a latch having a scan input terminal, a data input terminal, a clock input terminal and at least one output terminal for generating an output signal in response to a scan input signal received at the scan input terminal or a data input signal received at the data input terminal. The SC-SFF also includes a multiplexer having a scan clock input terminal, a functional clock input terminal and a clock output terminal, which is coupled with the clock input terminal of the latch, for providing the latch with either a scan clock received at the scan clock input terminal or a functional clock received at the functional input terminal, wherein the scan clock and the functional clock cause the latch to latch the scan input signal and the data input signal, respectively.

### BACKGROUND

The present invention relates generally to integrated circuit (IC) designs, and more particularly to a system of scan-based flip-flops.

Flip-flops are essential electronic devices for modern IC designs. Flip-flops are often connected in a chain formation with a scan design for circuit testing. Conventionally, the flip-flop has only one clock input terminal that receives both a functional clock for a normal operation and a scan clock for a scan mode. This creates a challenge to the clock tree design for a flip-flop chain because the shared clock input terminal is likely to induce timing violations.

Moreover, conventional flip-flop chains are particularly susceptible to current-resistance (IR) drop issues. The IR drop occurs when the flip-flop changes its value. During a scan mode, all of the flip-flops are toggling in response to the same clock event. When the flip-flops change their values at the same clock cycle, the combined IR drop may cause the flip-flop chain to behave abnormally. For example, the combined IR drop may exceed the specification allowed value by 3 times. In a serious case, this may cause the flip-flop chain to malfunction completely.

Thus, desirable in the art of scan-based flip-flop systems are designs that not only properly manage the functional and scan clocks, but also reduce the IR drop caused by the simultaneous toggling of flip-flops.

### SUMMARY

The present invention discloses a split clock flip-flop (SC-SFF). In one embodiment of the present invention, the SC-SFF includes a latch having a scan input terminal, a data input terminal, a clock input terminal and at least one output terminal for generating an output signal in response to a scan input signal received at the scan input terminal or a data input signal received at the data input terminal. The SC-SFF also includes a multiplexer having a scan clock input terminal, a functional clock input terminal and a clock output terminal, which is coupled with the clock input terminal of the latch, for providing the latch with either a scan clock received at the scan clock input terminal or a functional clock received at the functional input terminal, wherein the scan clock and the functional clock cause the latch to latch the scan input signal and the data input signal, respectively.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1 illustrates a diagram showing an IR drop caused by a flip-flop's change of value.

FIG. 2 illustrates a SC-SFF in accordance with one embodiment of the present invention.

FIG. 3 illustrates a SC-SFF system in accordance with another embodiment of the present invention.

### DESCRIPTION

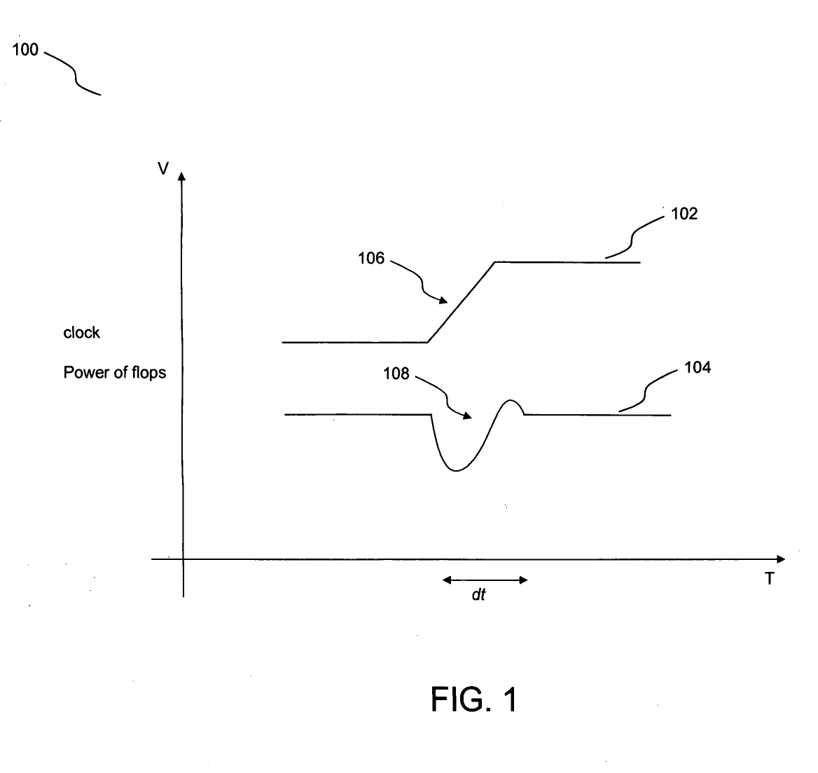

FIG. 1 illustrates a diagram showing an IR drop caused by a flip-flop's change of value. Graph 102 shows a relationship between time and voltage for a clock signal received by a flip-flop (not shown in the figure). Graph 104 shows a relationship between time and voltage for the power level of the flip-flop. As shown by the graph 102, the clock signal has a rising edge 106 between a low state and a high state to trigger the flip-flop to change its value. During the time (dt) when the flip-flop changes its value, its power level may experience a drop as indicated by the numeral 108.

Conventionally, during a scan mode, all of the flip-flops in a scan-based flip-flop chain toggles in response to the same clock event. All of the flip-flops change their values at the same time causes the power level to drop significantly, thereby reducing the stability of the flip-flop in scan operation.

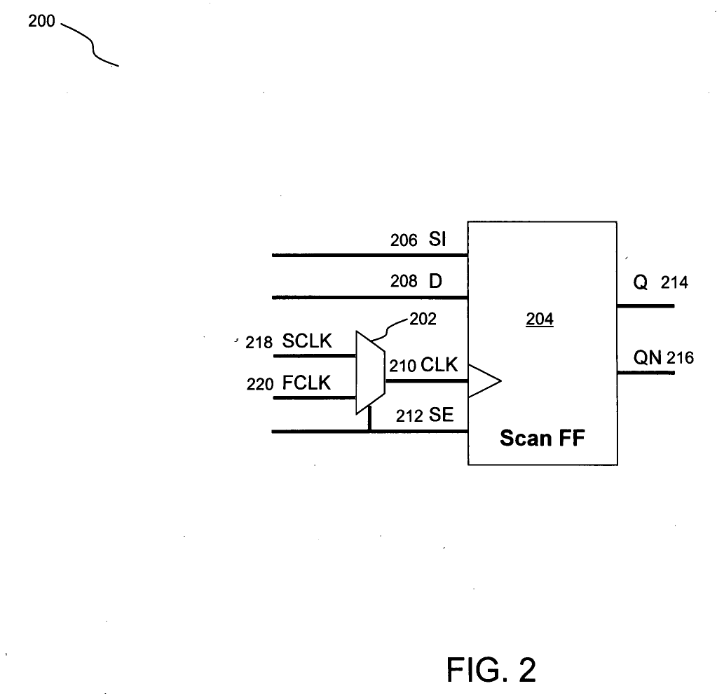

FIG. 2 illustrates a SC-SFF 200 in accordance with one embodiment of the present invention. The SC-SFF 200 includes a scan latch 204, also known as flip-flop, which has a scan input terminal (SI) 206, a data input terminal (D) 208, a clock input terminal (CLK) 210, a scan enable input terminal (SE) 212, an output terminal (Q) 214 and a complementary output terminal (QN) 216. The scan input terminal 206 is designed for receiving a scan input signal, while the data input terminal 208 is designed for receiving a data input signal. A multiplexer 202 has an output terminal coupled to the clock input terminal 210 of the scan latch 204. The multiplexer 202 has a scan clock input terminal (SCLK) for receiving a scan clock, and a functional clock input terminal (FCLK) for receiving a functional clock. The multiplexer 202 also has a scan enable input terminal (SE) for receiving a scan enable signal to control the multiplexer 202 to exclusively pass either the scan clock or the functional clock to the scan latch 204.

In a normal operation, the scan enable signal is not asserted so that only the functional clock can pass through the multiplexer 202 to the scan latch 204. The functional clock causes the scan latch 204 to latch the data input signal received at the data input terminal 208, thereby generating an output signal at the output terminal 214 and a complementary output signal at the complementary output terminal 216.

In a scan operation, the scan enable signal is asserted so that only the scan clock can pass through the multiplexer 202 to the scan latch 204. The scan clock causes the scan latch 204 to latch the scan input signal received at the scan input terminal 206, thereby generating an output signal at the output terminal 214 and a complementary output signal at the complementary output terminal 216. The data collected from the output signal can be analyzed for testing purposes.

In this embodiment, the multiplexer 202 only allows either the functional clock or the scan clock to pass to the scan latch 204. Thus, this reduces the chances of timing violation caused by improper balance of the functional and scan clocks. As a result, for a number of such SC-SFF's are coupled in a chain implemented in an IC, the task of designing the clock tree can be significantly simplified.

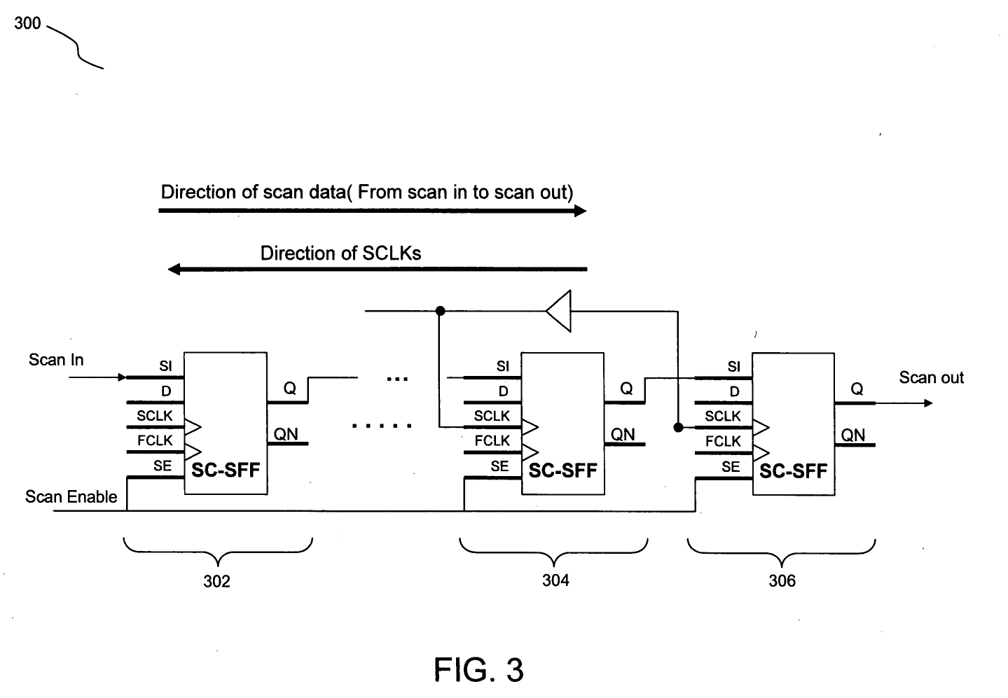

FIG. 3 illustrates a SC-SFF system 300 in accordance with another embodiment of the present invention. As shown in FIG. 2, the SC-SFF system 300 includes a plurality of SC-SFF's, each of which is identical to the SC-SFF 200 shown in FIG. 2. In the SC-SFF system 300, three exemplary SC-SFF's 302, 304, and 306 are shown to be connected in a chain formation, wherein the SC-SFF 302 is the first flip-flop, the SC-SFF 304 is the second to last flip-flop, and the SC-SFF 306 is the last flip-flop. The scan enable terminals (SE) of the SC-SFF's 302,304, and 306 are coupled together to receive the same scan enable signal. For the SC-SFF 302, the scan input terminal (SI) receives the scan input signal, while its output terminal (Q) is coupled to the scan input terminal of its subsequent SC-SFF, such as the SC-SFF 304. The SC-SFF's 304 and 306 are connected in the same manner with the exception that the output terminal (Q) of the SC-SFF 306 provides the final output signal of the system.

A scan clock input terminal (SCLK) and a functional clock input terminal (FCLK) of each SC-SFF 302, 304, or 306, are connected to a multiplexer (not shown in this figure) for preventing it from receiving both the clocks at the same time. The scan clock input terminals (SCLK's) are serially connected together with one or more delay modules interposed thereamong. The delay modules create timing differences for the scan clocks received by various SC-SFF's 302, 304 and 306. This prevents the SC-SFF's from changing their values at the same time, thereby distributing their IR drops over a longer period of time compared with the conventional flip-flop chains. As a result, the power level of flip-flop can be stabilized and the reliability of the system can be improved.

In this embodiment, the direction of the delay modules are in reverse to the travel direction of the scan input signal. For example, the san input signal travels along a direction from the SC-SFF 302 to the SC-SFF 306, while the delay module has an input terminal coupled to the SC-SFF 306 and an output terminal coupled to the SC-SFF 304. This arrangement allows the SC-SFF 306 to properly latch the data input signal in response to the received functional clock when the normal operation is switched to the scan mode. However, it is noted that in another embodiment, the direction of scan clock can be the same as that of the delay module depending on other design concerns.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A split clock flip-flop comprising:
a latch having a scan input terminal, a data input terminal, a clock input terminal and at least one output terminal for generating an output signal in response to a scan input signal received at the scan input terminal or a data input signal received at the data input terminal; and
a multiplexer having a scan clock input terminal, a functional clock input terminal and a clock output terminal, which is coupled with the clock input terminal of the latch, for providing the latch with either a scan clock received at the scan clock input terminal or a functional clock received at the functional input terminal,
wherein the scan clock and the functional clock cause the latch to latch the scan input signal and the data input signal, respectively.

2. The split clock flip-flop of claim 1, wherein the latch is a scan-based flip-flop.

3. The split clock flip-flop of claim 1, wherein the multiplexer further comprises a scan enable input terminal for receiving a scan enable signal to control the multiplexer to pass either the scan clock or the functional clock to the latch.

4. The split clock flip-flop of claim 1, wherein the latch further comprises a complementary output terminal for generating a complementary output signal.

5. A scan flip-flop system comprising:
a first split clock scan flip-flop having a first scan input terminal, a first scan clock input terminal, and at lest one first output terminal for generating a first output signal in response to a first scan input signal received at the first scan input terminal and latched by a first scan clock received at the first scan input clock terminal;
a delay module coupled to the first scan clock input terminal for delaying the first san clock; and
a second split clock scan flip-flop having a second scan input terminal coupled to the first output terminal, a second scan clock input terminal coupled to the first scan clock input terminal through the delay module, and a second output terminal for generating a second output signal in response to the first output signal received at the second scan input terminal and latched by a second scan clock received at the second scan clock input terminal, wherein the first scan clock and the second scan clock are shifted in timing.

6. The scan flip-flop system of claim 5, wherein the delay module comprises an input terminal coupled to the second scan clock input terminal, and an output terminal coupled to the first scan clock input terminal.

7. The scan flip-flop system of claim 5, wherein first split clock scan flip-flop comprises a first data input terminal for receiving a first data input signal.

8. The scan flip-flop system of claim 7, wherein the first split clock scan flip-flop comprises a first functional data input terminal for receiving a first functional clock that causes the first split clock scan flip-flop to latch the first data input signal.

9. The scan flip-flop system of claim 8, wherein the first split clock scan flip-flop comprises a first multiplexer coupled to the first scan clock and the first functional clock for controlling the first split clock scan flip-flop to pass either the first scan clock or the first functional clock.

10. The scan flip-flop system of claim 9, wherein the first split clock scan flip-flop comprises a first scan enable input terminal for receiving a first scan enable signal to cause the first multiplexer to pass either the first scan clock or the first functional clock.

11. The scan flip-flop system of claim 10, wherein the second split clock scan flip-flop comprises a second data input terminal for receiving a second data input signal.

12. The scan flip-flop system of claim 11, wherein the second split clock scan flip-flop comprises a second functional clock input terminal for receiving a second functional clock that causes the second split clock scan flip-flop to latch the second data input signal.

13. The scan flip-flop system of claim 12, wherein the second split clock scan flip-flop comprises a second multiplexer coupled to the second scan clock and the second functional clock for controlling the second split clock scan flip-flop to pass either the second scan clock or the second functional clock.

14. The scan flip-flop system of claim 13, wherein the second split clock scan flip-flop comprises a second scan enable input terminal coupled with the first scan enable input terminal for receiving the first scan enable signal to cause the second multiplexer to pass either the second scan clock or the second functional clock.

15. An integrated circuit comprising:
a first split clock scan flip-flop having a first scan input terminal, a first data input terminal, a first scan clock input terminal, a first functional clock input terminal, and at least one first output terminal for generating a first output signal in response to a scan input signal received at the first scan input terminal and latched by a first scan clock received at the first scan clock input terminal;
a delay module coupled to the first scan clock input terminal for delaying the first scan clock; and
a second split clock scan flip-flop having a second scan input terminal coupled to the first output terminal, a second data input terminal, a second scan clock input terminal coupled to the first scan clock input terminal through the delay module, a second functional clock input terminal, and a second output terminal for generating a second output signal in response to the first output signal received at the second scan input terminal and latched by a second scan clock received at the second scan clock input terminal, wherein the first scan clock and the second scan clock are shifted in timing.

16. The integrated circuit of claim 15, wherein the first and second functional clock input terminals receive first and second functional clocks for latching first and second data input signals received at the first and second data input terminals, respectively.

17. The integrated circuit of claim 16, wherein the first split clock scan flip-flop comprises a first multiplexer coupled to the first scan clock input terminal and the first functional clock input terminal for controlling the first split clock scan flip-flop to pass either the first scan clock or the first functional clock.

18. The integrated circuit of claim 17, wherein the second split clock scan flip-flop comprises a second multiplexer coupled to the second scan clock input terminal and the second functional clock input terminal for controlling the second split clock scan flip-flop to pass either the second scan clock or the second functional clock.

19. The integrated circuit of claim 18, further comprising a scan enable signal coupled to the first and second split clock scan flip-flops for controlling the first and second multiplexers to pass either the first and second scan clocks or the first and second functional clocks, respectively.

20. The integrated circuit of claim 19, wherein the delay module comprises an input terminal coupled to the second scan clock input terminal, and an output terminal coupled to the first scan clock input terminal.
